(19) United States
(12) Patent Application Publication
(10) Pub. No.: US 2026/0064918 A1
(43) Pub. Date: Mar. 5, 2026

(54) CONTEXT-BASED SAFETY SYSTEMS FOR SUBTERRANEAN ENVIRONMENT AND METHODS OF OPERATING THEREOF

(71) Applicant: LoopX Innovation Inc., Waterloo (CA)

(72) Inventors: Yaodong CUI, Waterloo (CA); Chao YU, Waterloo (CA); Jinwei ZHANG, Waterloo (CA)

(21) Appl. No.: 19/305,998

(22) Filed: Aug. 21, 2025

Related U.S. Application Data
(60) Provisional application No. 63/687,612, filed on Aug. 27, 2024.

(51) Int. Cl. G06F 30/27

(52) U.S. Cl. CPC G06F 30/27

(57) ABSTRACT

There is provided context-based safety systems, and methods for operating thereof, for a subterranean environment. An example context-based safety system for a subterranean environment includes: a plurality of sensors configured to collect a set of operating data; and a processor configured to: continuously receive the operating data from sensors, the set of operating data including at least one visual data; receive a user prompt from a user defining a risk assessment in respect of the operating data; apply the user prompt to a vision-language model to: identify one or more abnormal activities observed from the set of operating data, each abnormal activity being unexpected within a safety context associated with the subterranean environment and an activity type of that abnormal activity; and identify one or more risky activities from the abnormal activities for the risk assessment; and generate one or more recommendations in response to the risky activities.

### CROSS-REFERENCE TO RELATED PATENT APPLICATION

This application claims the benefit of U.S. Provisional Application No. 63/687,612, filed on Aug. 27, 2024. The complete disclosure of U.S. Provisional Application No. 63/687,612 is incorporated herein by reference.

### FIELD

The described embodiments relate to context-based safety systems, and methods for operating thereof, for a subterranean environment.

### BACKGROUND

Subterranean environments often pose operational challenges. The nature of the environment is associated with poor visibility, extreme temperatures, narrow passages, and/or geological instability, which can each cause challenges when construction equipment is involved.

For example, subterranean environments, such as underground mines (e.g., newly excavated drifts) often lack reliable network access. Building new network infrastructure takes time and is costly, and so, such environments often limit network infrastructure to main travel passages. In these settings, certain equipment, such as scoop trams, remain in areas where the network is unavailable or inconsistent for extended periods. Traditionally, it is very difficult to gather operational data within these inconsistent network environments. These environments typically rely on data provided via manual reporting, which can be unreliable, biased, and/or delayed. Other equipment that are in motion along various travel passages, such as dump trucks and human carriers, frequently move between inconsistent network environments and areas with network access. This can result in inconsistent connectivity throughout. As a result, operation analysis and optimization can typically only be conducted manually and are nearly impossible to achieve in real-time. This hinders the ability to promptly respond to operational changes and safety issues.

There is, therefore, a need for systems and methods that can consistently retrieve operational data from subterranean environments and automatically offer recommendations to identified risky activities.

### SUMMARY

The various embodiments described herein generally related to context-based safety systems, and methods for operating thereof, for a subterranean environment.

In accordance with an embodiment, there is provided a context-based safety system for a subterranean environment, the safety system includes: a plurality of sensors configured to collect a set of operating data within the subterranean environment; and a processor in communication with the plurality of sensors and configured to: continuously receive the set of operating data from the plurality of sensors, the set of operating data comprising at least one visual data; receive a user prompt from a user defining a risk assessment in respect of the set of operating data; apply the user prompt to a vision-language model to: identify one or more abnormal activities observed from the set of operating data, each abnormal activity being unexpected within a safety context associated with the subterranean environment and an activity type of that abnormal activity; and identify one or more risky activities from the one or more abnormal activities for the risk assessment; and generate one or more recommendations in response to the one or more risky activities.

In some embodiments, the processor is configured to apply the vision-language model to assign a risk level to each abnormal activity based on the safety context associated with the subterranean environment and that activity type.

In some embodiments, the processor is configured to: define a set of safety contexts associated with the subterranean environment for the vision-language model, the set of safety contexts identifying one or more situations related to one or more activities requiring safety compliance within the subterranean environment.

In some embodiments, the risk assessment comprises an operator performance assessment and the processor is configured to identify the one or more risky activities associated with operator performance, and generate the one or more recommendations for improving the operator performance.

In some embodiments, the risk assessment includes an environment safety assessment and the processor is configured to identify the one or more risky activities related to an unsafe environment, and generate the one or more recommendations for improving the unsafe environment.

In some embodiments, the processor is further configured to: generate a safety report in compliance with regulatory requirements for summarizing at least the one or more risky activities and the one or more recommendations.

In some embodiments, the plurality of sensors includes at least one sensor coupled to a machinery operating within the subterranean environment.

In some embodiments, the processor is further configured to: optimize the vision-language model with at least the set of operating data.

In accordance with an embodiment, there is provided a method for operating a context-based safety system for a subterranean environment, the method includes: collecting, by a plurality of sensors, a set of operating data within the subterranean environment; continuously receiving the set of operating data from the plurality of sensors, the set of operating data comprising at least one visual data; receiving a user prompt from a user defining a risk assessment in respect of the set of operating data; apply the user prompt to a vision-language model to: identify one or more abnormal activities observed from the set of operating data, each abnormal activity being unexpected within a safety context associated with the subterranean environment and an activity type associated to that abnormal activity; and identify one or more risky activities from the one or more abnormal activities for the risk assessment; and generate one or more recommendations in response to the one or more risky activities.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Several embodiments will now be described in detail with reference to the drawings, in which:

FIG. 1 is a block diagram of components in communication with a context-based safety system in accordance with an example embodiment;

FIG. 2 is a flowchart of an example method of operating the context-based safety system for a subterranean environment in accordance with an example embodiment;

FIG. 3A depicts a portion of an example subterranean environment in respect of which the context-based safety system can operate in accordance with an example embodiment;

FIG. 3B depicts the portion of the example subterranean environment of FIG. 3A in respect of which the context-based safety system can operate at a later time;

FIG. 4A is a screenshot from a video stream captured by a machinery operating within an example subterranean environment in accordance with an example embodiment;

FIG. 4B is another screenshot from the video stream at a later time from which FIG. 4A was captured by the machinery operating within an example subterranean environment in accordance with an example embodiment;

FIG. 4C is another screenshot from the video stream at a later time from which FIG. 4B was captured by the machinery operating within an example subterranean environment in accordance with an example embodiment;

FIG. 5A depicts an example activity observed from operating data collected from the example subterranean environment in accordance with an example embodiment;

FIG. 5B depicts another example activity observed from operating data collected from the example subterranean environment in accordance with an example embodiment;

FIG. 6 is a flowchart of an example method of operating the context-based safety system to identify risky activities within a subterranean environment in accordance with an example embodiment;

FIG. 7A depicts an example activity observed from operating data collected from the example subterranean environment in accordance with an example embodiment;

FIG. 7B depicts another example activity observed from operating data collected from the example subterranean environment in accordance with an example embodiment;

FIG. 8 is a screenshot of an example safety report generated by the context-based safety system in accordance with an example embodiment;

FIG. 9 depicts an example block diagram of environments with network access and inconsistent network access in accordance with an example embodiment; and

FIG. 10 depicts an example workflow diagram of an example operation with the context-based safety system in accordance with an example embodiment.

The drawings, described below, are provided for purposes of illustration, and not of limitation, of the aspects and features of various examples of embodiments described herein. For simplicity and clarity of illustration, elements shown in the drawings have not necessarily been drawn to scale. The dimensions of some of the elements may be exaggerated relative to other elements for clarity. It will be appreciated that for simplicity and clarity of illustration, where considered appropriate, reference numerals may be repeated among the drawings to indicate corresponding or analogous elements or steps.

### DESCRIPTION OF EXAMPLE EMBODIMENTS

With the growing prevalence of autonomous machinery as well as the ability to improve operations via data analytics and artificial intelligence (AI), the lack of connectivity, or consistent connectivity, is a technical challenge. This is especially true within an environment in which coordination of activities between unmanned and manned machinery relies on consistent communication and data sharing. In subterranean environments in which the rules governing surface traffic do not always apply (or are followed), it can be difficult to manage operations involving pedestrians and machineries that are in motion.

With the context-based safety systems and methods disclosed herein, operating data collected from the subterranean environment can be processed in order to enable improved reactions during interactions between machineries and/or pedestrians. Based on the operating data and insight generated by the context-based safety systems disclosed herein, various recommendations can be automatically generated for different audiences in response to detection of risky activities. The recommendations can relate to safety and/or productivity purposes.

The various embodiments described herein generally relate to context-based safety systems for subterranean environments, and associated methods for operating such systems.

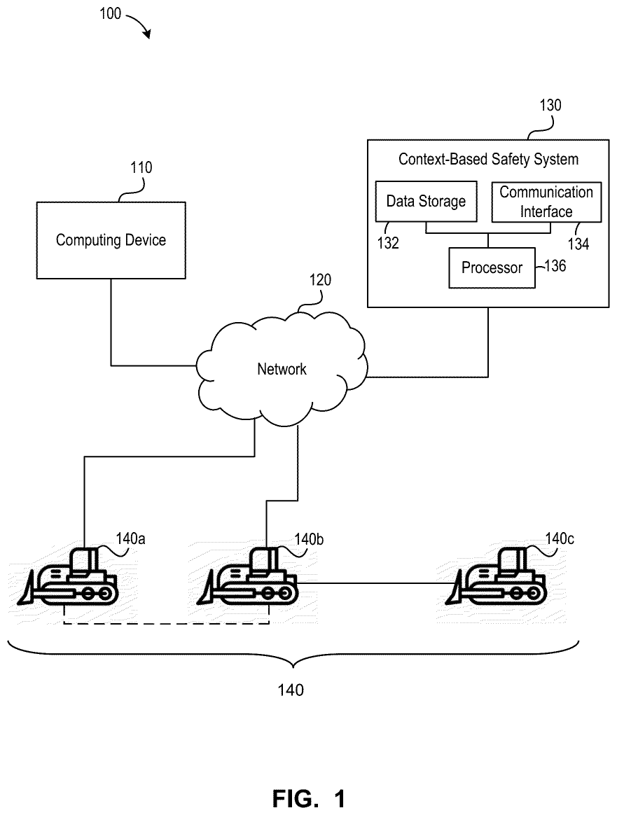

Reference is first made to FIG. 1, which illustrates a block diagram 100 of components engaging with a context-based safety system 130. The components include a computing device 110 and multiple machineries 140. The context-based safety system 130 can operate to communicate with the computing device 110 and the machinery 140 via the network 120. Although the context-based safety system 130 is shown in FIG. 1 as one entity, there may be multiple context-based safety systems 130 distributed over a wide geographic area and connected via the network 120, and/or the components of the context-based safety system 130 can be distributed across various geographic areas.

The context-based safety system 130 includes a processor 136, a data storage 132 and a communication interface 134. One or more of the processor 136, the data storage 132 and the communication interface 134 can be combined into fewer components or separated into further components. The processor 136, the data storage 132 and the communication interface 134 may be implemented in software or hardware, or a combination of software and hardware.

The processor 136 controls the operation of the context-based safety system 130. The processor 136 may be any suitable processor, controller or digital signal processor that can provide sufficient processing power depending on the configuration, purposes and requirements of the context-based safety system 130. In some embodiments, the processor 136 can include more than one processor with each processor being configured to perform different dedicated tasks.

The data storage 132 can include a database(s) or file system(s). The data storage 132 can store data related to the operation of the systems described herein, for example. The data storage 132 can include RAM, ROM, one or more hard drives, one or more flash drives, SD cards, or some other suitable data storage elements such as disk drives, etc. The data storage 132 may be used to store program code and configurations for controlling the systems and/or implementing the methods described herein.

The communication interface 134 can include a network communication interface. In embodiments in which elements are combined, the communication interface 134 may be a software communication interface, such as those for inter-process communication (IPC). In some embodiments, there may be a combination of communication interfaces implemented as hardware, software, and combination thereof. In some embodiments, the communication interface 132 may be any interface that enables the context-based safety system 130 to communicate with other devices and systems. In some embodiments, the communication interface 134 can include at least one of a serial port, a parallel port or a USB port. The communication interface 134 may also include at least one of an Internet, LAN, PAN, Ethernet, Firewire, modem or digital subscriber line connection. Various combinations of these elements may be incorporated within the communication interface 134. For example, the communication interface 134 may receive input from the computing device 110, or various input devices, such as a mouse, a keyboard, a touch screen, a thumbwheel, a track-pad, a track-ball, a card-reader, voice recognition software and the like depending on the requirements and implementation of the context-based safety system 130.

For exposition purposes, three different machineries 140a, 140b and 140c are shown. It is understood that fewer or a greater number of machineries 140 may be in communication with the context-based safety system 130 at any one time. In this example, machinery 140a and 140b are in direct communication with the context-based safety system 130, and machinery 140c is in communication with machinery 140b. Machineries 140a and 140b can also be in communication with each other. Generally, communication between the network 120 and machineries 140a and 140b can occur in real-time so that operating data can be collected and analyzed to generate comprehensive operational analytics. However, as discussed, there can be inconsistent network availability within such environments, and when network access is unavailable (or possibly when the network is unavailable for a certain time period), data may instead need to be relayed via V2V communication to machineries, such as 140a and 140b, that travel between inconsistent network areas and networked areas.

Machinery 140c in this example is not in communication with the network 120 directly and communicates with machinery 140b via various vehicle-to-vehicle (V2V) communications, such as but not limited to, dedicated short-range communications (DSRC), cellular vehicle-to-everything (C-V2X), Wi-Fi, Bluetooth, LiDAR, and ultra-wideband (UWB).

The computing device 110 can include any networked device operable to connect to the network 120. The computing device 110 can include at least a processor and memory, and may be an electronic tablet device, a personal computer, workstation, server, portable computer, mobile device, personal digital assistant, laptop, smart phone, WAP phone, an interactive television, video display terminals, gaming consoles, portable electronic devices or any combination of these. A networked device is a device capable of communicating with other devices through a network such as the network 120. A networked device may couple to the network 120 through a wired or wireless connection. For the context-based safety system 130, the computing device 110 can be used by a remote operator monitoring the machinery 140 and/or remotely operating the machinery 140. It is possible that the context-based safety system 130 can receive input or requests from the computing device 110 in respect of recommendations for the received operational data. Although only one computing device 110 is shown in FIG. 1, any number of computing devices 110 may be connected to the context-based safety system 130 via the network 120.

The computing device 110 can be coupled to the machinery 140 in some embodiments. For example, the computing device 110 can be an edge device, such as a Road Side Unit (RSU), which could be used to control multiple machineries 140 configured with a low-level controller. It is possible that the operator of the machinery 140 can engage with the machinery 140 remotely via the computing device 110. In such uses, the computing device 110 may be any device capable of providing inputs to operate the machinery 140 to perform functions such as movement and the actuation of components, such as but not limited to, a controller device containing various input controls, such as buttons, control sticks, or touch input devices. As another example, the computing device 110 could include a tablet configured with an application containing a user interface that allows inputs to be provided for controlling the machinery 140.

The network 120 can facilitate communication between the computing device 110, the context-based safety system 130, and the machinery 140. The network 120 can include any network capable of carrying data, including the Internet, Ethernet, plain old telephone service (POTS) line, public switch telephone network (PSTN), integrated services digital network (ISDN), digital subscriber line (DSL), coaxial cable, fiber optics, satellite, mobile, wireless (e.g. Wi-Fi, WiMAX), SS7 signaling network, fixed line, local area network (LAN), wide area network, controller area network (CAN bus), and others, including any combination of these, capable of interfacing with, and enabling communication between the computing device 110, the context-based safety system 130, and the machinery 140.

The network 120 can include a local network. For example, the local network can include a peer-to-peer network that facilitates communication between the machinery 140 locally. For example, external data networks may not be available in some work environments, such as subterranean environments and/or remote regions. As such, the local network can include peer-to-peer networks such as, but not limited to, near-me networks, personal area networks (PAN), and near-field communications technology. The local network can, in some embodiments, be implemented with Bluetooth™, wireless, and other similar network implementations.

In some embodiments, direct communication between the machinery can be enabled by the local network via infrared (IR) and/or radio frequency (RF) signals in accordance with proprietary protocols or other similar communication protocols. In some embodiments, the computing device 110 and machinery 140 can communicate through local means and then be capable of seamlessly switching to communicating through other available network infrastructure, such as Wi-Fi, when it does become available for connection.

In some embodiments, a remote data storage can be provided via the network 120.

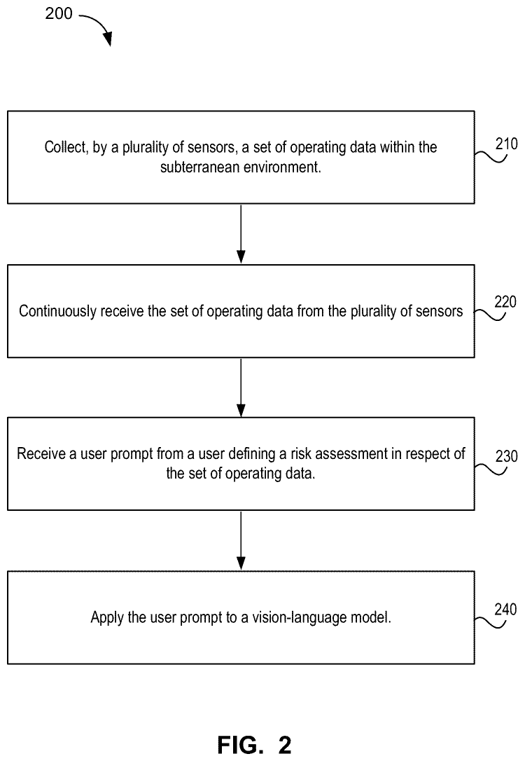

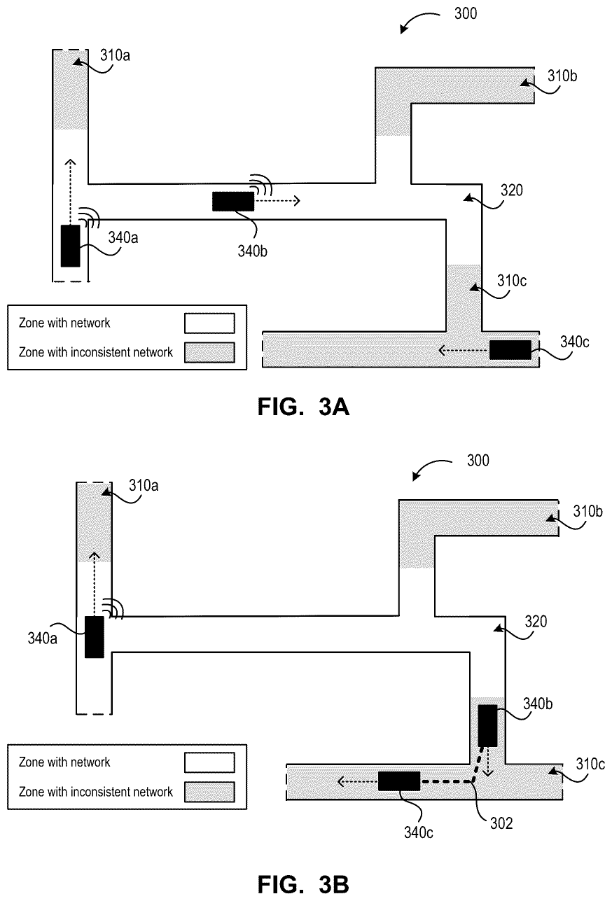

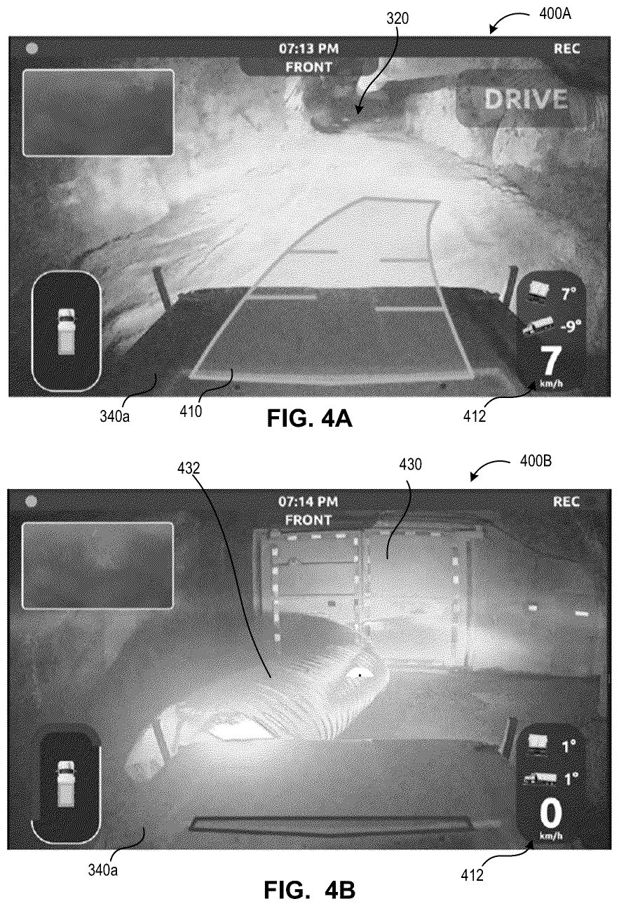

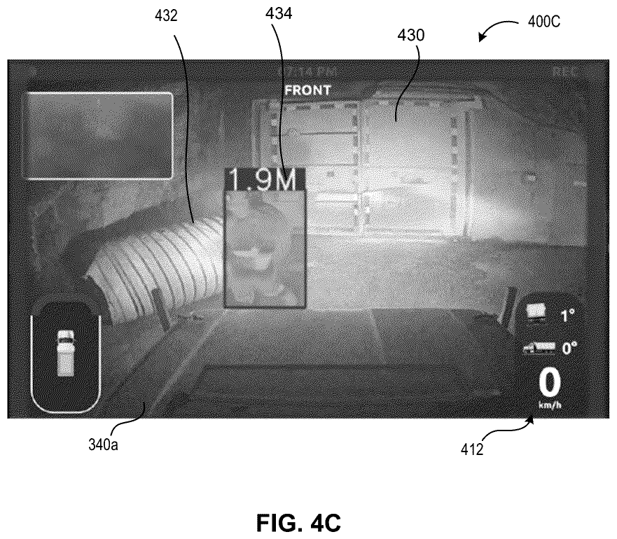

Reference will now be made with reference to FIG. 2. The flowchart 200 shows an example method for operating the context-based safety system 130 for a subterranean environment in accordance with an example embodiment. Reference will be simultaneously made to FIGS. 3A and 3B which respectively depict a portion of an example subterranean environment 300 at different times, and FIGS. 4A to 4C which are example screenshots from a video stream captured by a machinery operating within the subterranean environment 300.

At 210, a plurality of sensors collects a set of operating data within the subterranean environment 300.

The sensors can include various different types, including but not limited to: acceleration sensors for obtaining data related to vehicle dynamics, speed sensors for obtaining data related to operational efficiency and/or compliance with safety protocols for the subterranean environment 300, geo-location sensors for obtaining data related to vehicle movement within the subterranean environment 300, imaging and/or video sensors for capturing visual data to support contextual understanding of the interaction within the subterranean environment 300, and LiDAR/radar sensors for obtaining data to determine 3-dimensional (3D) information, such as but not limited to, distance and 3D coordinates. In some embodiments, the machinery 140 that navigates within the subterranean environment 300 can include various different vehicles for transporting humans and/or cargo, and can also include ego vehicles which are vehicles that contain sensors for perceiving the environment around the them. The related data collected from such vehicles can include data for identifying the types of equipment within its proximity, which can then adapt any data processing that may take place on such vehicles accordingly.

The plurality of sensors can include at least one sensor that is coupled to the machinery 140 operating within the subterranean environment 300. For example, one or more sensors may be built-in to the machinery 140. These sensors can begin to collect data upon detection of the machinery 140 engaging in operation and can continue to collect data until operation of that machinery 140 ceases.

The operating data can, in some embodiments, include contextual information provided by operators within the subterranean environment 300. The contextual information (e.g., ego vehicle type, operator identifier, and operation mode (e.g., hauling, dumping, etc.) can be provided manually from operators (remotely and/or within the subterranean environment 300) and/or automatically via sensors coupled to the machinery 140.

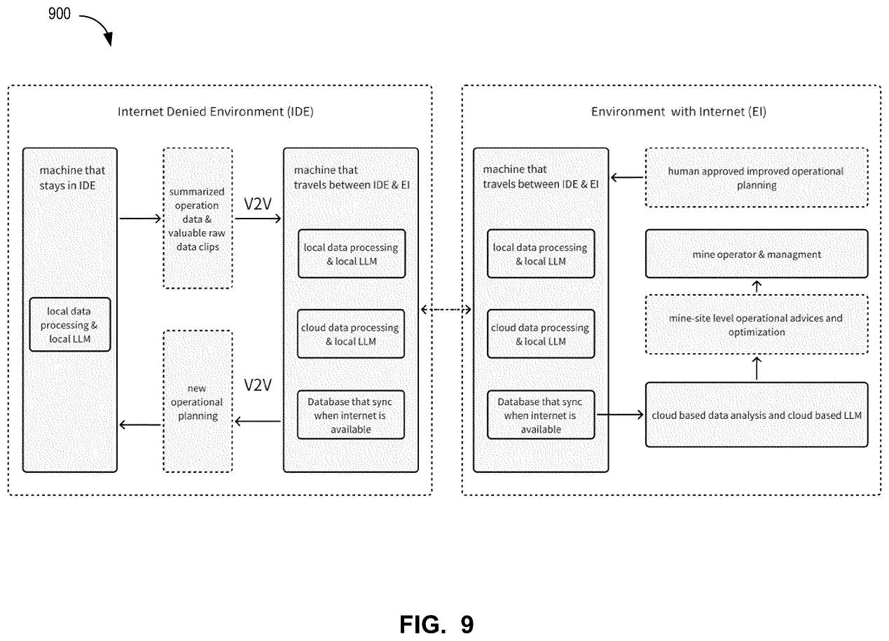

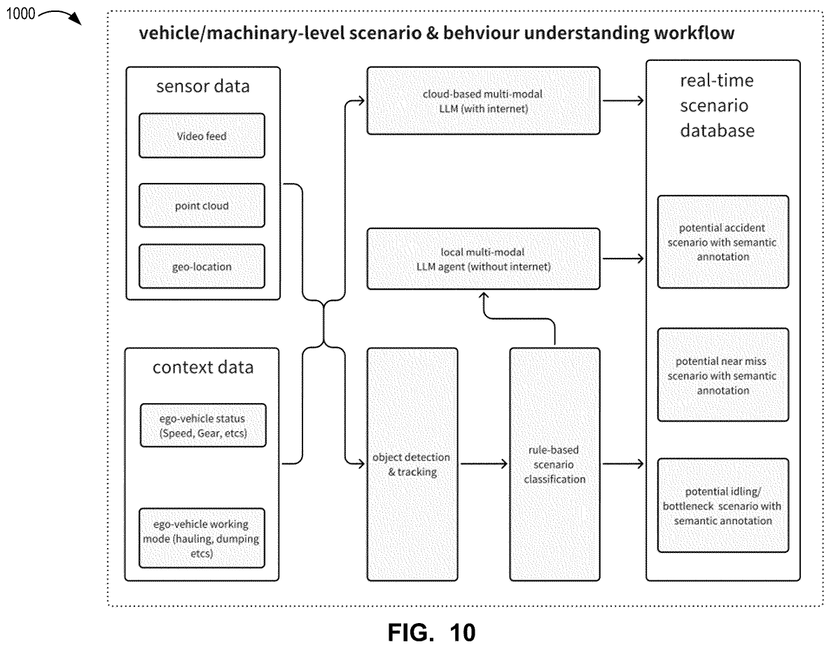

FIG. 3A shows a portion of the subterranean environment 300 in which three machineries 340a, 340b and 340c operate. There are zones with network (e.g., strong and/or consistent network strength), such as 320, and zones with inconsistent network (e.g., weak signal strength or no signal), such as 310a, 310b and 310c. During operation, machinery 340a can collect various operating data in respect of its own operation, as well as operating data in respect of the subterranean environment 300. As can be seen in FIG. 3A, machineries 340a and 340b are communicating with the network 120 during operation as they are within the networked zone 320. The network 120 with which the machineries 340a and 340b are communicating may be a local network within the subterranean environment 300 that can be connected to a wider ranged network. It is possible that machineries 340a and 340b can communicate with each other as well. However, as machinery 340c is within an inconsistent network zone 310c, there is no communication with the network 120 or any of machineries 340a and 340b. Continuing to FIG. 3B, as can be seen, machinery 340b has entered the inconsistent network zone 310c and has ceased communication with the network 120. Instead, machinery 340b can now communicate directly with machinery 340c via a peer-to-peer communication 302, for example. FIG. 9 depicts an example block diagram 900 of environments with network access and inconsistent network access in accordance with an example embodiment. FIG. 10 depicts an example workflow diagram 1000 of an example operation with the context-based safety system 130 in accordance with an example embodiment.

FIGS. 4A to 4C show example screenshots 400A to 400C captured from a video stream captured by a machinery 140, such as 340a, operating within the subterranean environment 300. In screenshot 400A, it can be seen that there is a projected path 410 for the machinery 340a as well as operating data 412, which are shown to include speed, incline experienced by the machinery 340a along its path, and a tilt angle of the machinery 340a along its path. It will be understood that other, or alternative, operating data 412 can be collected.

Screenshot 400B shows that the machinery 340a encountered obstacles 430, and 432 during its operation. Screenshot 400C shows that the machinery 340a also encountered a pedestrian 434 during its operation.

At 220, the context-based safety system 130 receives the set of operating data from the sensors.

The set of operating data includes at least one visual data. Examples are shown in FIGS. 4A to 4C. Visual data can offer important insight in respect of the subterranean environment 300. As explained, subterranean environments 300 are associated with unique characteristics (e.g., poor visibility, extreme temperatures, narrow passages, geological instability, etc.) that create operational challenges. By collecting operating data that at least includes visual data, the context-based safety system 130 can determine aspects of the operation of the machinery 140 and the subterranean environment 300 that can offer more comprehensive insight on any potential operational issues. When the set of operating data is received, the context-based safety system 130 can apply the large language models (as will be described) to identify and categorize the operating data. In some embodiments, certain activities identified by the large language models can be tagged for further analysis (along with other relevant operating data, such as raw video data clips and other data).

As described above, there can be instances when machineries 340a to 340c operate within zones with inconsistent network, such as 310c, and so, there can be delays from when the operating data is collected from the sensors to when the context-based safety system 130 receives the operating data. It may be that the machineries 140 within the subterranean environment 300 communicate to a local network first before the operating data is relayed to the context-based safety system 130. The operating data may be released in batches and/or when there is a slowdown in the network 120 to accommodate larger data transfers. In some embodiments, the operating data may be transmitted to the context-based safety system 130 continuously whenever the network 120 is available so that the operating data available to the context-based safety system 130 is as current as possible.

At 230, the context-based safety system 130 receives a user prompt from a user defining a risk assessment in respect of the set of operating data.

The user prompt can direct the context-based safety system 130 to generate the risk assessment that is relevant for the user, which is critical as the set of operating data can offer nearly limitless insight if not contained. The user prompt can include various forms, including natural language and/or prompted user selections. Example user prompts include but are not limited to: pre-defined task messages, data from task-related short-term memory (e.g., recent operating data from the machinery 140, operating data from other machines, information from other sources, including production planning software and mine traffic scheduling software), and data from task-related long-term memory (regulatory rules, site-specific rules, best practices). Based on the user prompt, the context-based safety system 130, with the assistance of large-language models where applicable, can determine the risk assessment that may be required by the user.

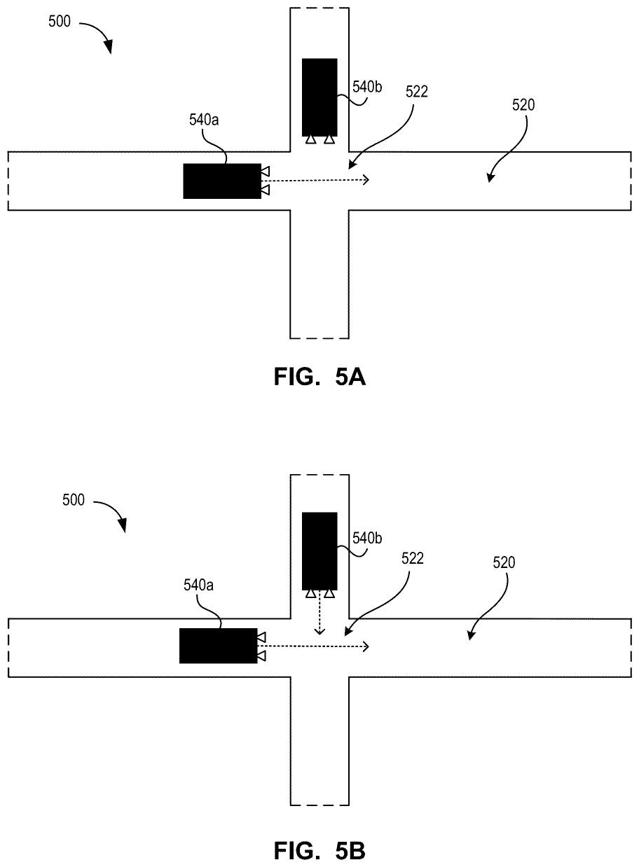

One example risk assessment can relate to an operator performance assessment. In this case, the context-based safety system 130 can identify one or more risky activities associated with operator performance from the set of operating data. Operating data can include but is not limited to recent operating data stored on a machine and information from production planning and mine traffic scheduling software. Risky activities can be subjective and so, as will be described below, the large language models (which can also include vision-language data models as an example) can offer guidance based on historically trained datasets. In some cases, the risky activities may vary depending on risk tolerances identified by the user, and/or for the subterranean environment 300. For example, FIGS. 5A and 5B illustrate an example portion of a subterranean environment 500 in different scenarios. In FIG. 5A, it can be seen that the machinery 540b stopped at the intersection 522 when approaching the main passage in which the machinery 540a is travelling. FIG. 5B, on the other hand, shows that the machinery 540b continues to be in motion despite approaching very quickly to the main passage and is about to engage in an incident with the machinery 540a. When evaluating the operating data collected from the scenario of FIG. 5B, the context-based safety system 130 can determine that the operator of the machinery 540b engaged in a risky activity by not safely stopping ahead of the intersection 522, which can result in an incident between the machineries 540a and 540b. The context-based safety system 130 can also automatically determine from the operating data being collected that the machineries 540a and 540b were approaching the intersection 522 and that the machinery 540a was travelling within the main passage, which requires the machinery 540b travelling within the subsidiary passage to stop. The context-based safety system 130 can then generate the recommendations for improving the operator performance (as will be described with respect to 430 below).

Another example risk assessment can include an environment safety assessment. The context-based safety system 130 can assess the operating data to identify risky activities related to an unsafe environment, and to then generate the recommendations for improving the unsafe environment. For example, FIG. 4B shows the obstacle 432 in front of the machinery 340a. The context-based safety system 130 can determine that the obstacle 432 is a ventilation pipe, which had fallen, since the visual data preceding 400B does not show the obstacle 432 (see FIG. 4A). The context-based safety system 130 can then determine from the operating data that there are some safety-related issues within the subterranean environment 300.

It will be understood that other forms of risk assessments may be available based on the user prompts.

At 240, the context-based safety system 130 applies the user prompt to a vision-language model.

The context-based safety system 130 can apply large language models (LLMs) to recognize and interpret relevant operational data from the set of operating data collected by the sensors. For example, depending on the context within which a machinery 140 is operating, a certain near-incident may not be as significant as another type of near-incident. The user prompt received at 230 can restrict the scope of the assessment to generate more relevant information for the user. The user prompt can be augmented with short-term and/or long-term memory.

Compared with traditional rule-based systems, the use of large language models can provide context-aware scenario and behavior understanding, common sense reasoning and/or summarization of operator activities, recommendations from operating data, short-term memory and/or long-term memory. This can lead to more accurate interpretations of complex operational environments, such as the subterranean environment 300. For example, the context-based safety system 130 can apply the large language models to analyze patterns within the operating data, sudden changes in speed or acceleration, proximity to other vehicles or obstacles, and unusual machinery behavior or operator actions. Once operational data is classified and tagged, large language models can interpret the data into semantically understandable and structured formats. This interpretation can significantly reduce the amount of operating data required generally. For example, from the operating data, the large language models can identify near-incidents (or “near-misses”) and append with semantic details, such as the type of event, contributing factors, and/or potential consequences had the incident occurred. This information is identified and logged, and can be used for post-event analysis and recommendations by the vision-language model (as will be described). As explained, the recommendations can relate to safety and/or productivity.

In some embodiments, the context-based safety system 130 applies a vision-language model. Vision-language models are data models that can associate information obtained from image and text. As explained, this can offer greater insight into the context in which the machinery 140 is operating alongside others within the subterranean environment 300. In some embodiments, the context-based safety system 130 can further optimize the vision-language model with short-term and/or long-term memory. A short-term memory could contain, but is not limited to, recent operating data. A long-term memory could contain, but is not limited to, regulatory regulations, site-specific regulations, and best practices, etc.

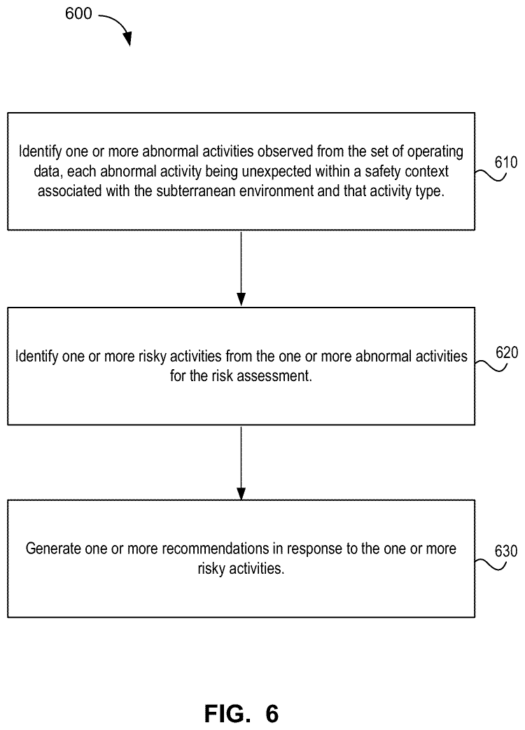

FIG. 6 shows an example method 600 of operating the context-based safety system 130 for identifying risky activities within the subterranean environment 300 in accordance with an example embodiment.

At 610, the context-based safety system 130 identifies one or more abnormal activities observed from the set of operating data.

Abnormal activities are those activities that are unexpected within a safety context associated with the subterranean environment 300 and that activity type. Examples of abnormal activities include but are not limited to: activities that violate site-specific rules, activities that do not follow best practices, and activities that violate traffic scheduling.

The context-based safety system 130 can define a set of safety contexts associated with the subterranean environment 300 for the large language model. The set of safety contexts identifies situation(s) related to activities that require safety compliance within the subterranean environment 300. The safety context will vary in severity depending on various factors, including the type of activity and location within the subterranean environment 300. For example, during blasting, the safety context is critical as there can be severe consequences if safety protocols are not properly adhered to. It is likely that in such critical safety contexts, exact guidelines on activity near the activity zone must be maintained, such as safety distances, hazard gears, etc. There can be other guidelines for other areas of the subterranean environment 300 as well. Accordingly, the activities that are considered abnormal and/or risky during a critical safety context can be more severe than in other safety contexts. For instance, any individual approaching a machinery 140 conducting the blasting can trigger a risky activity as there can be certain approaches that are highly risky, whereas during a loading activity, it is expected for individuals to be approaching such machinery 140 conducting the loading activity, which would not trigger a risky activity alert.

In safety contexts that are less critical (e.g., basic safety context), such as when a machinery 140 is carrying individuals and/or cargo along passages at low speed, the activities considered abnormal and/or risky can be less severe. For example, during transit, individuals can likely walk alongside such machineries 140 operating at low speed along the passageway. This would not be identified as a risky activity—in contrast to activities such as drilling, digging, blasting, etc.

Accordingly, the safety contexts enable the context-based safety system 130 to distinguish between the impact that one activity may have in different settings, and to automatically offer insight accordingly.

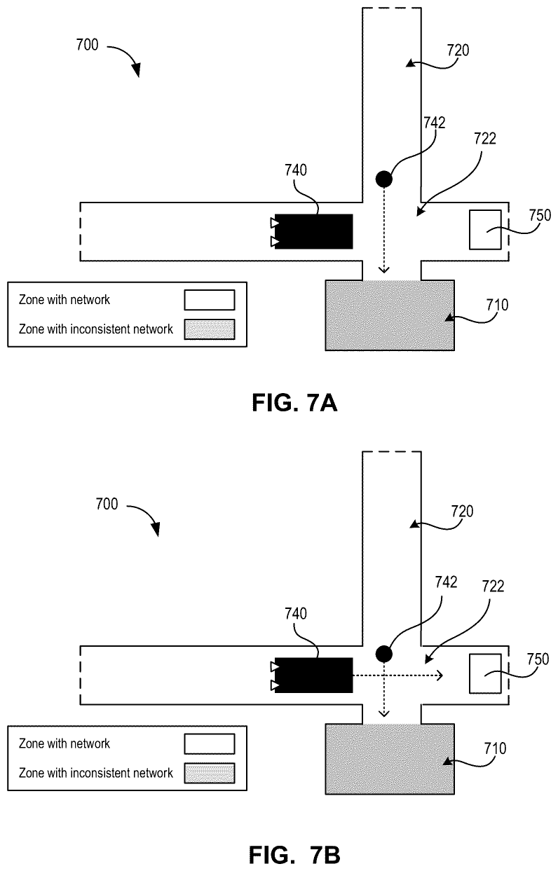

For example, FIG. 5A shows the normal activity expected from machineries 540a and 540b approaching the intersection 522, whereas FIG. 5B shows an abnormal activity being machinery 540b not stopping ahead of the intersection 522. Similarly, FIGS. 7A and 7B show another example portion of a subterranean environment 700 with different scenarios. The subterranean environment 700 includes an inconsistent network zone 710 and a network zone 720, with an obstacle 750 (which could be a target for the machinery 740). In FIG. 7A, an individual 742 is approaching an intersection 722 and the machinery 740 has stopped. In FIG. 7B, both the individual 742 and the machinery 740 continue to be in motion as they approach the intersection 722, which is likely to lead to an incident. The motion of the individual 742 is an abnormal activity.

Similarly, as shown in FIGS. 4A to 4C, the obstacle 432 obstructing the path of the machinery 340a is an abnormal activity that can be identified by the context-based safety system 130 as it is abnormal for obstacles like the ventilation pipe 432 to be on the ground. The individual 434 identified in FIG. 4C is also an abnormal activity as it is not typical for individuals to be approaching machinery 140 that closely and from the front of the machinery 340a.

At 620, the context-based safety system 130 identifies one or more risky activities from the one or more abnormal activities for the risk assessment.

The context-based safety system 130 can apply the large language model to assign a risk level to each abnormal activity based on the safety context associated with the subterranean environment 300 and that activity type. As described, each abnormal activity will be associated with a different risk profile depending on the safety context.

Continuing with the example shown in FIGS. 4A to 4C, the risk level is minimal as the ventilation pipe 432 had low engagement with the machinery 430a. However, the context-based safety system 130 will likely indicate that there is risk involved due to falling infrastructure, and offer recommendations accordingly.

In the example shown in FIGS. 5B and 7B, the context-based safety system 130 can identify those abnormal activities to be risky as those can result in severe collisions, and offer recommendations accordingly.

At 630, the context-based safety system 130 generates recommendation(s) in response to the one or more risky activities.

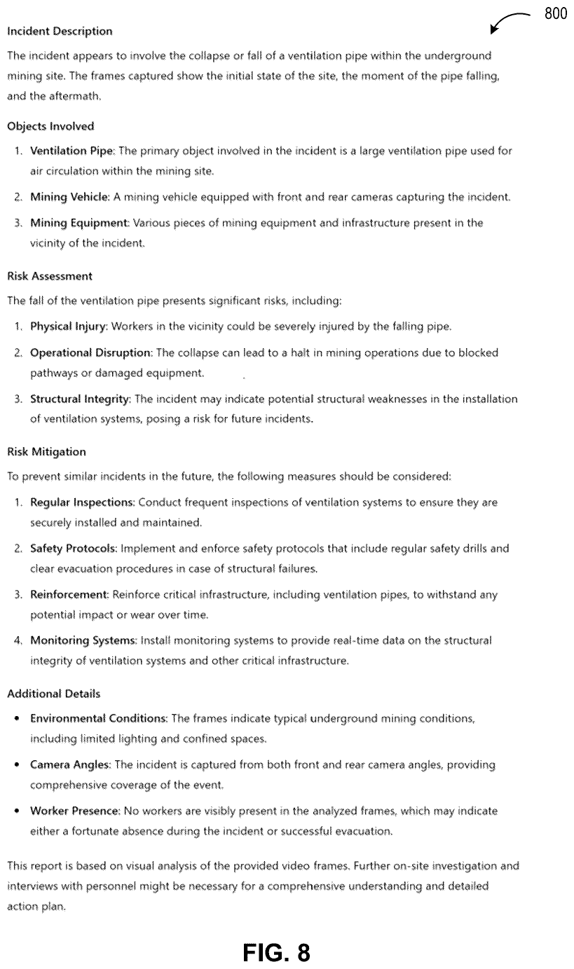

The context-based safety system 130 can generate a safety report that is in compliance with regulatory requirements. For example, the safety report can summarize the risky activities identified and offer related recommendations. The recommendations can be targeted to different audiences, including but not limited to machinery operators and mine-site planners. An example safety report, generally at 800, is shown in FIG. 8.

The safety report 800 can include various information, including nearly missed incidents, recommendations for productivity based on work profile usage data, productivity reports, and performance review information (e.g., safety incidents, behavioral patterns, performance metrics, recommendations for additional training for operators, etc.), and administrator reports (e.g., safety trends across work site, recommendations for adjustments in procedures, training, maintenance, predictive analytics, etc.). It will be understood that other information can be generated within the safety report 800 as required by the user of the context-based safety system 130, and/or other reports can be generated for other purposes from the set of operating data collected. It will also be understood that the recommendations can be generated from the same set of operating data in such a way to target different audiences with different sets of actionable terms.

It will be appreciated that numerous specific details are set forth in order to provide a thorough understanding of the example embodiments described herein. However, it will be understood by those of ordinary skill in the art that the embodiments described herein may be practiced without these specific details. In other instances, well-known methods, procedures and components have not been described in detail so as not to obscure the embodiments described herein. Furthermore, this description and the drawings are not to be considered as limiting the scope of the embodiments described herein in any way, but rather as merely describing the implementation of the various embodiments described herein.

The embodiments of the systems and methods described herein may be implemented in hardware or software, or a combination of both. These embodiments may be implemented in computer programs executing on programmable computers, each computer including at least one processor, a data storage system (including volatile memory or non-volatile memory or other data storage elements or a combination thereof), and at least one communication interface. For example and without limitation, the programmable computers (referred to below as computing devices) may be a server, network appliance, embedded device, computer expansion module, a personal computer, laptop, personal data assistant, cellular telephone, smart-phone device, tablet computer, a wireless device or any other computing device capable of being configured to carry out the methods described herein.

In some embodiments, the communication interface may be a network communication interface. In embodiments in which elements are combined, the communication interface may be a software communication interface, such as those for inter-process communication (IPC). In still other embodiments, there may be a combination of communication interfaces implemented as hardware, software, and combination thereof.

Program code may be applied to input data to perform the functions described herein and to generate output information. The output information is applied to one or more output devices, in known fashion.

Each program may be implemented in a high level procedural or object oriented programming and/or scripting language, or both, to communicate with a computer system. However, the programs may be implemented in assembly or machine language, if desired. In any case, the language may be a compiled or interpreted language. Each such computer program may be stored on a storage media or a device (e.g. ROM, magnetic disk, optical disc) readable by a general or special purpose programmable computer, for configuring and operating the computer when the storage media or device is read by the computer to perform the procedures described herein. Embodiments of the system may also be considered to be implemented as a non-transitory computer-readable storage medium, configured with a computer program, where the storage medium so configured causes a computer to operate in a specific and predefined manner to perform the functions described herein.

Furthermore, the system, processes and methods of the described embodiments are capable of being distributed in a computer program product comprising a computer readable medium that bears computer usable instructions for one or more processors. The medium may be provided in various forms, including one or more diskettes, compact disks, tapes, chips, wireline transmissions, satellite transmissions, internet transmission or downloadings, magnetic and electronic storage media, digital and analog signals, and the like. The computer useable instructions may also be in various forms, including compiled and non-compiled code.

Various embodiments have been described herein by way of example only. Various modification and variations may be made to these example embodiments without departing from the spirit and scope of the invention, which is limited only by the appended claims.

We claim:

1. A context-based safety system for a subterranean environment, the safety system comprises:
a plurality of sensors configured to collect a set of operating data within the subterranean environment; and
a processor in communication with the plurality of sensors and configured to:
continuously receive the set of operating data from the plurality of sensors, the set of operating data comprising at least one visual data;
receive a user prompt from a user defining a risk assessment in respect of the set of operating data;
apply the user prompt to a vision-language model to:
identify one or more abnormal activities observed from the set of operating data, each abnormal activity being unexpected within a safety context associated with the subterranean environment and an activity type of that abnormal activity; and
identify one or more risky activities from the one or more abnormal activities for the risk assessment; and
generate one or more recommendations in response to the one or more risky activities.

2. The context-based safety system of claim 1, wherein the processor is configured to apply the vision-language model to assign a risk level to each abnormal activity based on the safety context associated with the subterranean environment and that activity type.

3. The context-based safety system of claim 1, wherein the processor is configured to:
define a set of safety contexts associated with the subterranean environment for the vision-language model, the set of safety contexts identifying one or more situations related to one or more activities requiring safety compliance within the subterranean environment.

4. The context-based safety system of claim 1, wherein the risk assessment comprises an operator performance assessment and the processor is configured to identify the one or more risky activities associated with operator performance, and generate the one or more recommendations for improving the operator performance.

5. The context-based safety system of claim 1, wherein the risk assessment comprises an environment safety assessment and the processor is configured to identify the one or more risky activities related to an unsafe environment, and generate the one or more recommendations for improving the unsafe environment.

6. The context-based safety system of claim 1, wherein the processor is further configured to:
generate a safety report in compliance with regulatory requirements for summarizing at least the one or more risky activities and the one or more recommendations.

7. The context-based safety system of claim 1, wherein the plurality of sensors comprises at least one sensor coupled to a machinery operating within the subterranean environment.

8. The context-based safety system of claim 1, wherein the processor is further configured to:
optimize the vision-language model with at least the set of operating data.

9. A method for operating a context-based safety system for a subterranean environment, the method comprises:
collecting, by a plurality of sensors, a set of operating data within the subterranean environment;
continuously receiving the set of operating data from the plurality of sensors, the set of operating data comprising at least one visual data;
receiving a user prompt from a user defining a risk assessment in respect of the set of operating data;
apply the user prompt to a vision-language model to:
identify one or more abnormal activities observed from the set of operating data, each abnormal activity being unexpected within a safety context associated with the subterranean environment and an activity type associated to that abnormal activity; and
identify one or more risky activities from the one or more abnormal activities for the risk assessment; and
generate one or more recommendations in response to the one or more risky activities.

10. The method of claim 9, wherein the processor is further operated to apply the vision-language model to assign a risk level to each abnormal activity based on the safety context associated with the subterranean environment and that activity type.

11. The method of claim 9, wherein the processor is further operated to define a set of safety contexts associated with the subterranean environment for the vision-language model, the set of safety contexts identifying one or more situations related to one or more activities requiring safety compliance within the subterranean environment.

12. The method of claim 9, wherein the risk assessment comprises an operator performance assessment and the processor is further operated to identify the one or more risky activities associated with operator performance, and generate the one or more recommendations for improving the operator performance.

13. The method of claim 9, wherein the risk assessment comprises an environment safety assessment and the processor is further operated to identify the one or more risky activities related to an unsafe environment, and generate the one or more recommendations for improving the unsafe environment.

14. The method of claim 9, wherein the processor is further operated to generate a safety report in compliance with regulatory requirements for summarizing at least the one or more risky activities and the one or more recommendations.

15. The method of claim 9, wherein the plurality of sensors comprises at least one sensor coupled to a machinery operating within the subterranean environment.

16. The method of claim 9, wherein the processor is further operated to optimize the vision-language model with at least the set of operating data.
